(19) United States
(12) Patent Application Publication
(10) Pub. No.: US 2023/0420515 A1
(43) Pub. Date: Dec. 28, 2023

(54) INTEGRATED CIRCUIT SEMICONDUCTOR DEVICE

(71) Applicant: SAMSUNG ELECTRONICS CO., LTD., Suwon-si (KR)

(72) Inventor: Sungmin KIM, Suwon-si (KR)

(21) Appl. No.: 18/214,861

(22) Filed: Jun. 27, 2023

(30) Foreign Application Priority Data
Jun. 28, 2022 (KR) 10-2022-0079262

(51) Int. Cl. H01L 29/06; H01L 29/423; H01L 29/66; H01L 29/775; H01L 29/786; H01L 27/088; H01L 21/8238; H10B 10/00

(52) U.S. Cl. CPC H01L 29/0673; H01L 29/42376; H01L 29/66439; H01L 29/775; H01L 29/78696; H01L 27/088; H01L 21/823807; H01L 21/823828; H10B 10/12; H10B 10/18

(57) ABSTRACT

An integrated circuit semiconductor device includes a first transistor on a substrate. The first transistor includes a first gate electrode. A second transistor is on the substrate and is spaced apart from the first transistor. The second transistor includes a second gate electrode directly connected to the first gate electrode. A recess region is recessed in surfaces of the first and second gate electrodes and is arranged between the first and second gate electrodes. A first width of a first sidewall of the first gate electrode is less than a second width of a second sidewall of the first gate electrode adjacent to the recess region and opposite the first sidewall. A third width of a third sidewall of the second gate electrode is less than a fourth width of a fourth sidewall of the second gate electrode adjacent to the recess region and opposite the third sidewall.

### CROSS-REFERENCE TO RELATED APPLICATION

This application claims priority under 35 U.S.C. § 119 to Korean Patent Application No. 10-2022-0079262, filed on Jun. 28, 2022 in the Korean Intellectual Property Office, the disclosure of which is incorporated by reference in its entirety herein.

### 1. Technical Field

The present inventive concept relates to an integrated circuit semiconductor device, and more particularly, to an integrated circuit semiconductor device capable of reducing parasitic capacitance.

### 2. Discussion of Related Art

Integrated circuit semiconductor devices may include transistors on substrates. The integration level of transistors has increased to satisfy high performance demanded by consumers. However, as the integration level of the integrated circuit semiconductor devices increases a parasitic capacitance between elements constituting the integrated circuit semiconductor devices has also increased. The increase in parasitic capacitance may reduce an operation speed of integrated circuit semiconductor devices and reduce the reliability of the transistors.

### SUMMARY

Embodiments of the present inventive concept provide an integrated circuit semiconductor device having an increased operation speed by reducing parasitic capacitance.

According to an embodiment of the present inventive concept, an integrated circuit semiconductor device includes a first transistor on a substrate. The first transistor includes a first gate electrode. A second transistor is on the substrate and is spaced apart from the first transistor. The second transistor includes a second gate electrode directly connected to the first gate electrode. A recess region is recessed in surfaces of the first and second gate electrodes and is arranged between the first and second gate electrodes. A first width of a first sidewall of the first gate electrode is less than a second width of a second sidewall of the first gate electrode adjacent to the recess region and opposite the first sidewall. A third width of a third sidewall of the second gate electrode is less than a fourth width of a fourth sidewall of the second gate electrode adjacent to the recess region and opposite the third sidewall.

According to an embodiment of the present inventive concept, an integrated circuit semiconductor device includes a first active fin on a substrate. A first multi-bridge channel transistor is on the first active fin. The first multi-bridge channel transistor includes a first gate electrode. A second active fin is on the substrate and is spaced apart from the first active fin. A second multi-bridge channel transistor is on the second active fin. The second multi-bridge channel transistor includes a second gate electrode that is directly connected to the first gate electrode. A recess region is recessed in surfaces of the first gate electrode and the second gate electrode and is arranged between the first gate electrode and the second gate electrode. A first height of a first sidewall of the first gate electrode is greater than a second height of a second sidewall of the first gate electrode adjacent to the recess region and opposite the first sidewall. A third height of a third sidewall of the second gate electrode is greater than a fourth height of a fourth sidewall of the second gate electrode adjacent to the recess region and opposite the third sidewall.

According to an embodiment of the present inventive concept, an integrated circuit semiconductor device includes a first active fin on a substrate. A first multi-bridge channel transistor is on the first active fin. The first multi-bridge channel transistor includes a first gate electrode. A second active fin is on the substrate and is spaced apart from the first active fin. A second multi-bridge channel transistor is on the second active fin. The second multi-bridge channel transistor includes a second gate electrode that is directly connected to the first gate electrode. A recess region is recessed in surfaces of the first gate electrode and the second gate electrode and is arranged between the first gate electrode and the second gate electrode. A first width of a first sidewall of the first gate electrode is less than a second width of a second sidewall of the first gate electrode adjacent to the recess region and opposite the first sidewall. A third width of a third sidewall of the second gate electrode is less than a fourth width of a fourth sidewall of the second gate electrode adjacent to the recess region and opposite the third sidewall. A first height of the first sidewall of the first gate electrode is greater than a second height of the second sidewall of the first gate electrode adjacent to the recess region and opposite the first sidewall. A third height of the third sidewall of the second gate electrode is greater than a fourth height of the fourth sidewall of the second gate electrode adjacent to the recess region and opposite the third sidewall.

### BRIEF DESCRIPTION OF THE DRAWINGS

Embodiments of the present inventive concept will be more clearly understood from the following detailed description taken in conjunction with the accompanying drawings in which:

FIG. 1 is a layout diagram of an integrated circuit semiconductor device according to an embodiment of the present inventive concept;

FIG. 2 is a cross-sectional view taken along line II-II′ of FIG. 1 according to an embodiment of the present inventive concept;

FIG. 3 is a cross-sectional view taken along line III-III′ of FIG. 1 according to an embodiment of the present inventive concept;

FIG. 4 is a partial detailed cross-sectional view illustrating FIG. 3 according to an embodiment of the present inventive concept;

FIGS. 5 to 15 are cross-sectional views illustrating a method of manufacturing an integrated circuit semiconductor device of FIGS. 3 and 4 according to embodiments of the present inventive concept;

FIG. 16 is a block diagram illustrating a structure of a semiconductor chip including an integrated circuit semiconductor device, according to an embodiment of the present inventive concept;

FIG. 17 is a block diagram illustrating a structure of a semiconductor chip including an integrated circuit semiconductor device, according to an embodiment of the present inventive concept;

FIG. 18 is a block diagram illustrating a structure of an electronic device including an integrated circuit semiconductor device, according to an embodiment of the present inventive concept; and

FIG. 19 is an equivalent circuit diagram of a static random access memory (SRAM) cell, according to an embodiment of the present inventive concept.

### DETAILED DESCRIPTION OF EMBODIMENTS

Hereinafter, embodiments of the present inventive concept will be described in detail with reference to the accompanying drawings. Embodiments of the present inventive concept below may be implemented via only one embodiment, and may also be implemented via combinations of one or more embodiments. Therefore, the scope of embodiments of the present inventive concept is not construed as being limited to one embodiment.

As used herein, the singular forms of elements are intended to include the plural forms as well, unless the context clearly indicates otherwise. As used herein, the drawings are exaggerated to more clearly explain embodiments of the present inventive concept.

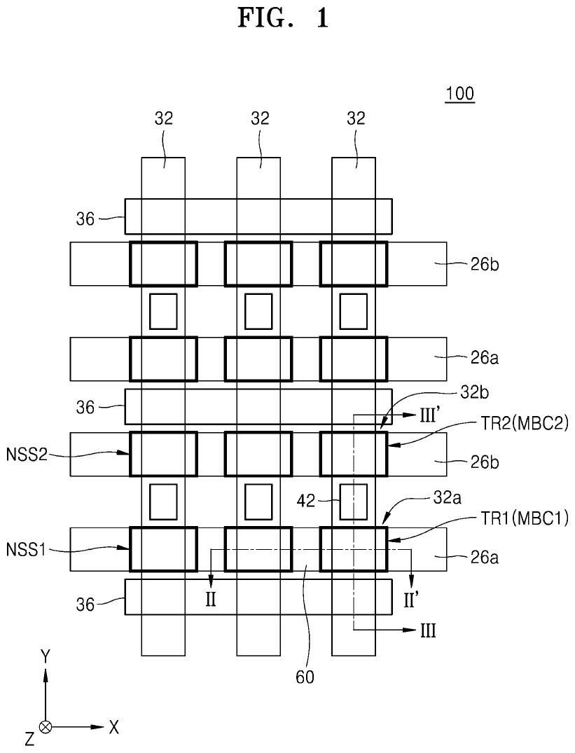

FIG. 1 is a layout diagram of an integrated circuit semiconductor device according to an embodiment.

FIG. 1 illustrates that a first direction (e.g., an X direction) may be a channel length direction, and a second direction (e.g., a Y direction) may be a channel width direction. Hereinafter, a layout of an integrated circuit semiconductor device 100 will be described in more detail, and embodiments of the present inventive concept are not necessarily limited to the layout diagram of FIG. 1.

The integrated circuit semiconductor device 100 may include a plurality of active fins extending in the first direction (the X direction), and spaced apart from each other in the second direction (the Y direction). The active fins may be P-type active fins or N-type active fins. In an embodiment, the active fins may include first active fins 26a and second active fins 26b. However, the number of the active fins may vary and may include three or more active fins in some embodiments.

For convenience, the active fins are divided into the first active fins 26a and the second active fins 26b. The first active fins 26a may provide active regions of first transistors TR1. The second active fins 26b may provide active regions of second transistors TR2.

The integrated circuit semiconductor device 100 may include a plurality of gate electrodes 32 extending in the second direction (the Y direction) perpendicular to the first direction (the X direction), and spaced apart from each other in the first direction (the X direction). The integrated circuit semiconductor device 100 may include a plurality of gate cutting regions 36 extending in the first direction (the X direction), and spaced apart from each other in the second direction (the Y direction).

The gate cutting regions 36 may be regions cutting the gate electrodes 32 in the second direction (the Y direction). The gate electrodes 32 may not be connected to each other in the second direction (the Y direction) due to the gate cutting regions 36.

The gate cutting regions 36 may each be arranged between two active fins, such as between the first active fin 26a and the second active fin 26b, in the second direction (the Y direction). FIG. 1 illustrates that the gate cutting regions 36 cut all the gate electrodes 32 in the first direction (the X direction). However, in an embodiment the gate cutting regions 36 may cut only some of the gate electrodes 32, e.g., only one or two of the gate electrodes 32, in the first direction (the X direction) and at least one of the gate electrodes 32 may be connected to each other in the second direction (the Y direction). The gate electrodes 32 may include first gate electrodes 32a and second gate electrodes 32b. The first gate electrodes 32a and the second gate electrodes 32b may extend and be connected to each other in the second direction (the Y direction).

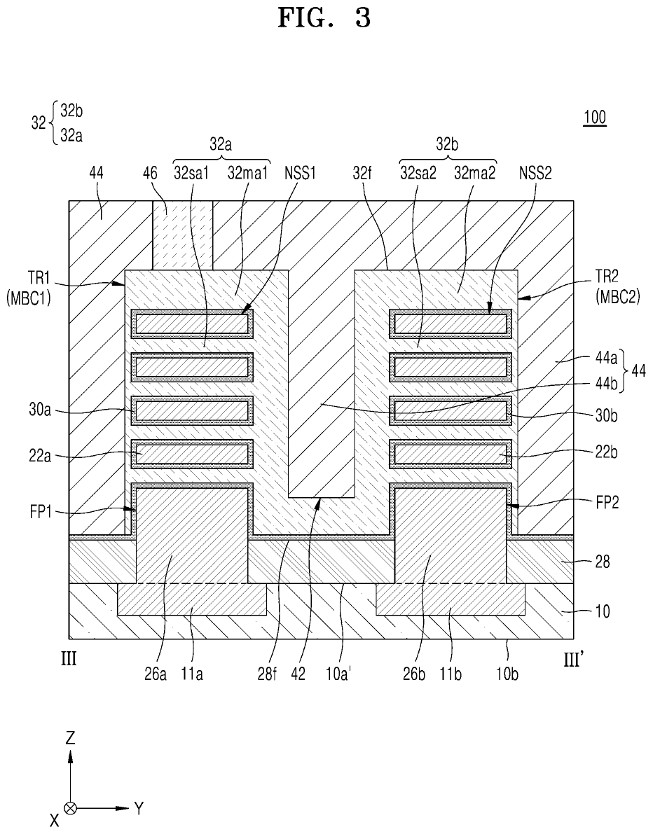

The integrated circuit semiconductor device 100 may include recess regions 42 formed between the first gate electrodes 32a and the second gate electrodes 32b in the second direction (the Y direction). The recess regions 42 may be regions recessed in surfaces of the first gate electrodes 32a and the second gate electrodes 32b as shown in FIG. 3.

In some embodiments, a width of the recess regions 42 in the first direction (the X direction) may be less than a width of the gate electrodes 32 in the first direction (the X direction). However, embodiments of the present disclosure are not necessarily limited thereto. For example, in some embodiments, the width of the recess regions 42 in the first direction (the X direction) may be equal to the width of the gate electrodes 32 in the first direction (the X direction). A vertical structure of the recess regions 42 is described in detail below.

The integrated circuit semiconductor device 100 may include nanosheet stacking structures NSS1 and NSS2 located at overlapping portions at which the active fins 26a and 26b and the gate electrodes 32 cross each other. Source and drain regions 60 may be formed on both sides of the nanosheet stacking structures NSS1 and the NSS2 in the first direction (the X direction).

In an embodiment, the nanosheet stacking structures NSS1 and NSS2 may include first nanosheet stacking structures NSS1 and second nanosheet stacking structures NSS2. However, embodiments of the present disclosure are not necessarily limited thereto and the num er of nanosheet stacking structures may vary. A vertical structure of the nanosheet stacking structures NSS1 and NSS2 is described in detail below.

In an embodiment, the first nanosheet stacking structures NSS1 may be formed at overlapping portions at which the first active fins 26a and the gate electrodes 32 cross each other. The second nanosheet stacking structures NSS2 may be formed at overlapping portions at which the second active fins 26b and the gate electrodes 32 cross each other.

The integrated circuit semiconductor device 100 may include transistors including the nanosheet stacking structures NSS1 and NSS2 and the gate electrodes 32, which are formed at overlapping portions at which the active fins 26a and 26b and the gate electrodes 32 cross each other. In an embodiment, the transistors may include first transistors TR1 and second transistors TR2. However, embodiments of the present disclosure are not necessarily limited thereto and the number of transistors may vary.

In an embodiment, the transistors, such as the first and second transistors TR1 and TR2, may be solid transistors, such as three-dimensional transistors. The transistors, such as the first and second transistors TR1 and TR2, may include multi-bridge channel transistors, such as first and second multi-bridge channel transistors MBC1 and MBC2, including the nanosheet stacking structures, such as the first and second nanosheet stacking structures NSS1 and NSS2, and the gate electrodes 32. The multi-bridge channel transistors may include first multi-bridge channel transistors MBC1 and second multi-bridge channel transistors MBC2. However, embodiments of the present disclosure are not necessarily limited thereto and the number of the multi-bridge channel transistors may vary.

In an embodiment, the first multi-bridge channel transistors MBC1 may be formed at overlapping portions at which the first active fins 26a and the gate electrodes 32 cross each other, by including the first nanosheet stacking structures NSS1 and the first gate electrodes 32a. The second multi-bridge channel transistors MBC2 may be formed at overlapping portions at which the second active fins 26b and the gate electrodes 32 cross each other, by including the second nanosheet stacking structures NSS2 and the second gate electrodes 32b.

The integrated circuit semiconductor device 100 described above may reduce a parasitic capacitance between the first and second gate electrodes 32a and 32b and peripheral elements by reducing, in the second direction (the Y direction), an area of sidewalls or an area of sides of the first and second gate electrodes 32a and 32b via the gate cutting regions 36.

The integrated circuit semiconductor device 100 may reduce the parasitic capacitance between the first and second gate electrodes 32a and 32b and the peripheral elements by reducing the total area of the first and second gate electrodes 32a and 32b via the recess regions 42. The peripheral elements described above may include well regions formed in a substrate, the source and drain regions 60, and adjacent gate electrodes or lines. Accordingly, the integrated circuit semiconductor device 100 may increase an operation speed by reducing parasitic capacitance.

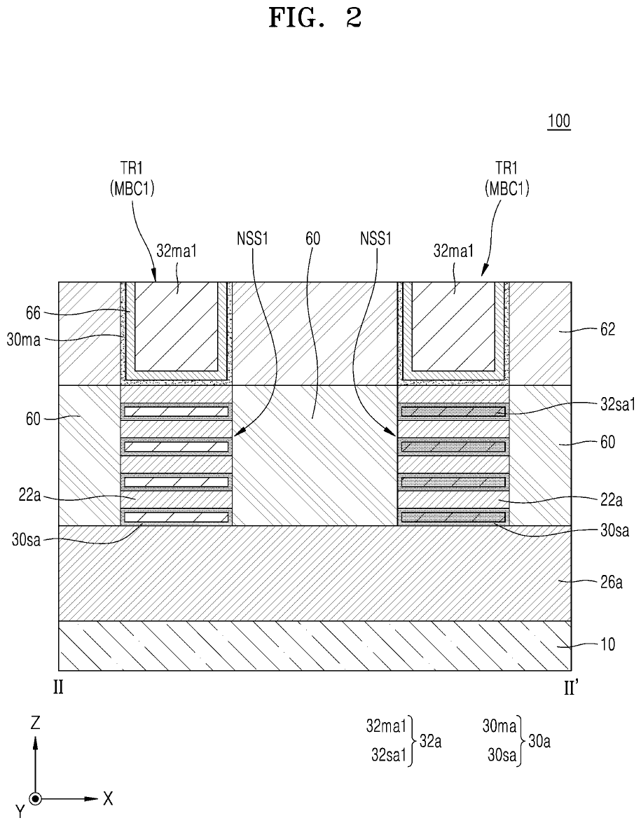

FIG. 2 is a cross-sectional view taken along line II-II′ of FIG. 1.

In an embodiment, an integrated circuit semiconductor device 100 may include first transistors TR1 formed on a first active fin 26a to be spaced apart from each other. The first transistors TR1 are first multi-bridge channel transistors MBC1. As illustrated in FIG. 2, a first direction (an X direction) may be a channel length direction of the first multi-bridge channel transistors MBC1.

In an embodiment, the integrated circuit semiconductor device 100 may include a substrate 10, and the first active fin 26a formed on the substrate 10. First nanosheet stacking structures NSS1, which are spaced apart from each other (e.g., in the X direction), are formed on the first active fin 26a. Each of the first nanosheet stacking structures NSS1 may include a plurality of first nanosheets 22a spaced apart from each other in a third direction (a Z direction).

Each of the first nanosheet stacking structures NSS1 may include a plurality of first nanosheets 22a spaced apart from each other in the third direction (the Z direction) perpendicular to an upper surface of the substrate 10. The Z direction may be a thickness direction of the substrate 10 and may be perpendicular to the X and Y directions. In an embodiment, the first nanosheets 22a may include silicon layers.

First sub gate insulating layers 30sa surrounding the first nanosheets 22a are formed on the first active fin 26a. In an embodiment, the first sub gate insulating layers 30sa are formed on upper and lower surfaces and sides of the first nanosheets 22a. First main gate insulating layers 30ma are respectively formed on the uppermost first nanosheets 22a (e.g., the first nanosheet 22a that is farthest from an upper surface of the substrate 10 in the Z direction). In an embodiment, the first main gate insulating layers 30ma may be formed of the same material as the first sub gate insulating layers 30sa. The first sub gate insulating layers 30sa and the first main gate insulating layers 30ma may be referred to as first gate insulating layers 30a.

First sub gate electrodes 32sa1 are formed on the first sub gate insulating layers 30sa, and between the first nanosheets 22a (e.g., in the Z direction). First main gate electrodes 32ma1 are respectively formed above the uppermost first nanosheets 22a. The first sub gate electrodes 32sa1 and the first main gate electrodes 32ma1 may be referred to as first gate electrodes 32a, In some embodiments, barrier metal layers 66 may be respectively formed above the uppermost first nanosheets 22a and on both sidewalls of the first main gate electrodes 32ma1.

Source and drain regions 60 may be formed under both sides of the first main gate electrodes 32ma1, and on both sides of the first nanosheet stacking structures NSS1 (e.g., in the X direction). The source and drain regions 60 may have an embedded SiGe structure or the like including epitaxially grown Si layers, epitaxially grown SiC layers, and a plurality of epitaxially grown SiGe layers. An interlayer insulating layer 62 may be formed on circumferences of the first main gate electrodes 32ma1.

FIG. 3 is a cross-sectional view taken along line III-III′ of FIG. 1.

In an embodiment, an integrated circuit semiconductor device 100 may include a first transistor TR1 and a second transistor TR2 spaced apart from each other (e.g., in the Y direction) on a substrate 10. The first transistor TR1 and the second transistor TR2 may be a first multi-bridge channel transistor MBC1 and a second multi-bridge channel transistor MBC2, respectively As illustrated in FIG. 3, a second direction (a Y direction) may be a channel width direction of the second multi-bridge channel transistor MBC2.

In an embodiment, the integrated circuit semiconductor device 100 may include the substrate 10 and well regions, such as first and second well regions 11a and 11b. The substrate 10 may include a surface 10a′ and a back surface 10b. A first well region 11a is formed in a portion of the substrate 10. A second well region 11b is formed in a portion of the substrate 10 and spaced apart from the first well region 11a. (e.g., in the Y direction). The first well region 11a and the second well region 11b may be P-type well regions or N-type well regions.

A first active fin 26a is foamed in the first well region 11a. A second active fin 26b is formed in the second well region 11b. The first active fin 26a and the second active fin 26b may be P-type active fins or N-type active fins. An isolation layer 28 is formed to surround lower circumferences of the first active fin 26a and the second active fin 26b.

The first active fin 26a may include a first fin protrusion FP1 protruding from a surface 28f of the isolation layer 28 (e.g., in the Z direction). The second active fin 26b may include a second fin protrusion FP2 protruding from the surface 28f of the isolation layer 28 (e.g., in the Z direction). A first nanosheet stacking structure NSS1 is formed on the first active fin 26a. The first nanosheet stacking structure NSS1 may include a plurality of first nanosheets 22a spaced apart from each other in a third direction (the Z direction).

In an embodiment shown in FIG. 3, four first nanosheets 22a are stacked. However, embodiments of the present inventive concept are not necessarily limited thereto and more or less first nanosheets 22a may be stacked. In an embodiment, the first nanosheets 22a may include silicon layers.

A second nanosheet stacking structure NSS2 is formed on the second active fin 26b. The second nanosheet stacking structure NSS2 may include a plurality of second nanosheets 22b spaced apart from each other in the third direction (the Z direction). The second nanosheet stacking structure NSS2 may include a plurality of second nanosheets 22b spaced apart from each other in the third direction (the Z direction) perpendicular to the surface 10a′ of the substrate 10.

In an embodiment shown in FIG. 3, four second nanosheets 22b are stacked. However, embodiments of the present inventive concept are not necessarily limited thereto and more or less second nanosheets 22b may be stacked. In an embodiment, the second nanosheets 22b may include silicon layers.

First gate insulating layers 30a surrounding the first nanosheets 22a are formed on the first active fin 26a. The first gate insulating layers 30a are formed on the first active fin 26a. The first gate insulating layers 30a extend from the first active fin 26a onto the isolation layer 28 in the second direction (the Y direction).

Second gate insulating layers 30b surrounding the second nanosheets 22b are formed on the second active fin 26b. The second gate insulating layers 30b are formed on the second active fin 26b. The second gate insulating layers 30b extend from the second active fin 26b onto the isolation layer 28 in the second direction (the Y direction).

A gate electrode 32 is formed on the first gate insulating lavers 30a on the first nanosheet stacking structure NSS1 and the second gate insulating layers 30b on the second nanosheet stacking structure NSS2. The gate electrode 32 includes a first gate electrode 32a and a second gate electrode 32b. In an embodiment, the first gate electrode 32a and the second gate electrode 32b are physically and electrically connected to each other. For example, the first gate electrode 32a and the second gate electrode 32b may have a same body (e.g., are integral with each other).

In an embodiment, the first gate electrode 32a may be formed on the first gate insulating lavers 30a on the first nanosheet stacking structure NSS1. The first gate electrode 32a may include a first sub gate electrode 32sa1 and a first main gate electrode 32ma1.

The first sub gate electrode 32sa1 may be formed between the first gate insulating layer on the first active fin 26a and the lowermost first nanosheet 22a and between the first gate insulating layers 30a on the first nanosheets 22a.

The first main gate electrode 32ma1 may be formed on the first gate insulating layer 30a on the uppermost first nanosheet 22a and on the first gate insulating layers 30a on sidewalk of the first nanosheets 22a.

The second gate electrode 32b may be formed on the second gate insulating layers 30b on the second nanosheet stacking structure NSS2. The second gate electrode 32b may include a second sub gate electrode 32sa2 and a second main gate electrode 32ma2.

The second sub gate electrode 32sa2 may be formed between the second gate insulating layer 30b on the second active fin 26b and the lowermost second nanosheet 22b and between the second gate insulating layers 30b on the second nanosheets 22b.

The second main gate electrode 32ma2 may be formed on the second gate insulating layer 30b on the uppermost second nanosheet 22b and on the second gate insulating layers 30b on sidewalls of the second nanosheets 22b.

A recess region 42 may be formed between the first gate electrode 32a and the second gate electrode 32b. The recess region 42 may be a region recessed in a surface 32f of the first gate electrode 32a and the second gate electrode 32b. As described above, the integrated circuit semiconductor device 100 may reduce a parasitic capacitance between the first and second gate electrodes 32a and 32b and peripheral elements by reducing the total area of the first and second gate electrodes 32a and 32b via the recess region 42. Accordingly, the integrated circuit semiconductor device 100 may increase an operation speed by reducing parasitic capacitance.

The integrated circuit semiconductor device 100 may include an interlayer insulating layer 44 and a gate contact 46. The interlayer insulating layer 44 may be formed on the gate electrode 32 in which the recess region 42 is formed. The interlayer insulating layer 44 may include a first portion 44a formed on top and sidewalk of the gate electrode 32, and a second portion 44b buried in the recess region 42. In an embodiment, the gate contact 46 may be formed on top of the first gate electrode 32a and connected to the first gate electrode 32a.

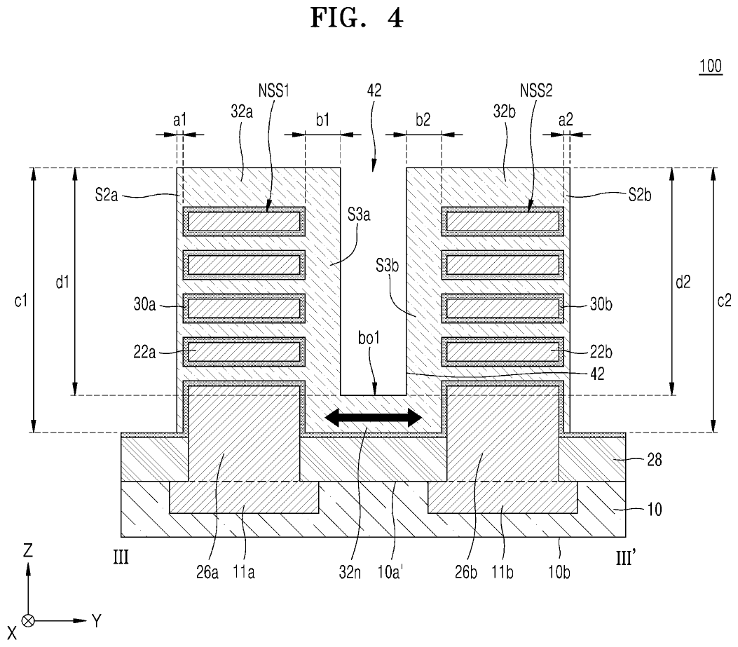

FIG. 4 is a partial detailed cross-sectional view illustrating FIG. 3.

In an embodiment, an integrated circuit semiconductor device 100 includes a first gate electrode 32a and a second gate electrode 32b. A recess region 42 is formed between the first gate electrode 32a and the second gate electrode 32b in a second direction (the Y direction). The recess region 42 may include a bottom portion bo1.

In some embodiments, the bottom portion bo1 of the recess region 42 may be positioned at a lower level than upper surfaces of the first fin protrusion FP1 and the second fin protrusion FP2 of FIG. 3. In some embodiments, the bottom portion bo1 of the recess region 42 may be positioned between the upper surface of the first fin protrusion FP1 of FIG. 3 and a lower surface of a lowermost first nanosheet 22a. In some embodiments, the bottom portion bo1 of the recess region 42 may also be positioned between the upper surface of the second fin protrusion FP2 of FIG. 3 and a lower surface of a lowermost second nanosheet 22b.

The first gate electrode 32a and the second gate electrode 32b may be connected to each other (e.g., directly connected to each other) as indicated by the double-headed arrow in FIG. 4. The first gate electrode 32a and the second gate electrode 32b may include a connection portion 32n.

The first gate electrode 32a may include a first sidewall S2a and a second sidewall S3a. The first sidewall S2a may be formed on the first gate insulating layers 30a on a first sidewall of a first nanosheet stacking structure NSS1 (e.g., a sidewall on a first side of the first nanosheet stacking structure NSS1 in the Y direction). The second sidewall S3a may be formed on the first gate insulating layers 30a on an opposite second sidewall of the first nanosheet stacking structure NSS1 adjacent to the recess region 42 (e.g., a sidewall on an opposite second side of the first nanosheet stacking structure NSS1 in the Y direction).

In an embodiment, a first width a1 (e.g., length in the Y direction) of the first sidewall S2a of the first gate electrode 32a may be less than a second width b (e.g., length in the Y direction) of the second sidewall S3a of the first gate electrode 32a adjacent to the recess region 42. The first width a1 and the second width b1 may be widths in the second direction (the Y direction). In an embodiment, a first height c1 (e.g., length in the Z direction) of the first sidewall S2a of the first gate electrode 32a may be greater than a second height d1 of the second sidewall S3a of the first gate electrode 32a adjacent to the recess region 42.

An area of the first sidewall S2a of the first gate electrode 32a may be less than an area of the second sidewall S3a of the first gate electrode 32a. Accordingly, a parasitic capacitance between the first gate electrode 32a and peripheral elements may be reduced.

The second gate electrode 32b may include a third sidewall S2b and a fourth sidewall S3b. The third sidewall S2b may be formed on the second gate insulating layers 30b on a first sidewall of a second nanosheet stacking structure NSS2 (e.g., a sidewall on a first side of the second nanosheet stacking structure NSS2 in the Y direction). The fourth sidewall S3b may be formed on the second gate insulating layers 30b on an opposite second side-wall of the second nanosheet stacking structure NSS2 adjacent to the recess region 42 (e.g., a sidewall on an opposite second side of the second nanosheet stacking structure NSS2 in the Y direction).

In an embodiment, a third width a2 (e.g., length in the Y direction) of the third sidewall S2b of the second gate electrode 32b may be less than a fourth width b2 (e.g., length in the Y direction) of the fourth sidewall S3b of the second gate electrode 32b adjacent to the recess region 42. The third width a2 and the fourth width b2 may be widths in the second direction (the direction). In an embodiment, a third height c2 (e.g., length in the Z direction) of the third sidewall S2b of the second gate electrode 32b may be greater than a fourth height d2 (e.g., length in the Z direction) of the fourth sidewall S3b of the second gate electrode 32b adjacent to the recess region 42.

In some embodiments, the first width a1 may be equal to the third width a2. The second width b1 may be equal to the fourth width b2. The first height c1 may be equal to the third height c2. The second height d1 may be equal to the fourth height d2.

An area of the third side-wall S2b of the second gate electrode 32b may be less than an area of the fourth sidewall S3b of the second gate electrode 32b. Accordingly, a parasitic capacitance between the second gate electrode 32b and peripheral elements may be reduced.

As described above, the integrated circuit semiconductor device 100 may reduce a parasitic capacitance between the first and second gate electrodes 32a and 32b and peripheral elements by reducing an area of sidewalls (or an area of sides) of the first and second gate electrodes 32a and 32b.

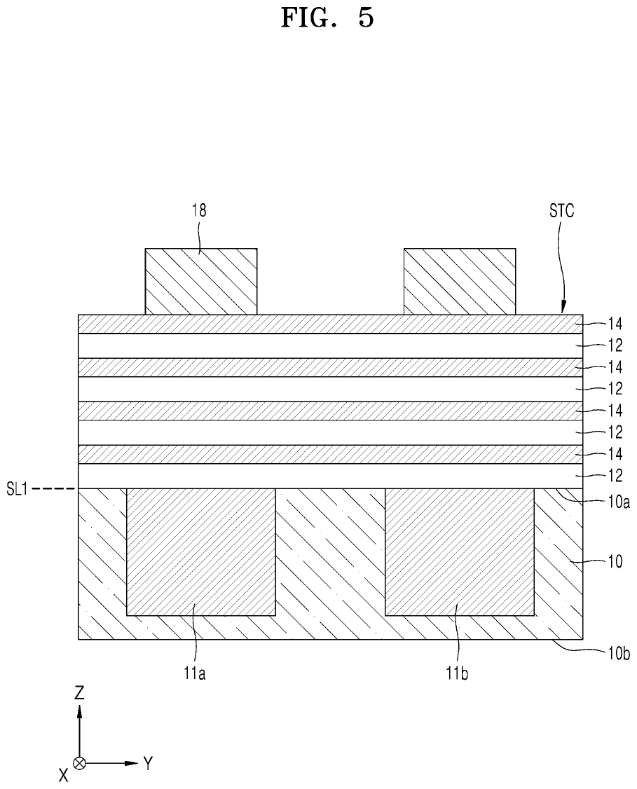

FIGS. 5 to 15 are cross-sectional views illustrating a method of manufacturing an integrated circuit semiconductor device of FIGS. 3 and 4.

In an embodiment, the same reference numerals of FIGS. 5 to 15 as those of FIGS. 3 and 4 denote the same elements. The same description of FIGS. 5 to 15 as that of FIGS. 3 and 4 is briefly given or omitted herein.

Referring to FIG. 5, a substrate 10 is provided. The substrate 10 may have a surface 10a and a back surface 110b that are spaced apart in the Z direction. In some embodiments, the substrate 10 may include a semiconductor, such as Si or Ge, or a compound semiconductor, such as SiGe, SiC, GaAs, InAs, or MP. In an embodiment, the substrate 10 may include at least one of a group III-V material and a group IV material.

The group III-V material may be a binary, ternary, or quaternary compound including at least one group III element and at least one group V element. The group III-V material may be a compound including at least one of In, Ga, and Al as the group III element, and at least one of As, P, and Sb as the group V element.

For example, in an embodiment the group III-V material may be selected from InP, InzGal-zAs (0≤z≤1), and AlzGal-zAs (0≤z≤1). The binary compound may be, for example, any one of InP, GaAs, InAs, InSb, and GaSb. The ternary compound may be any one of InGaP, InciaAs, AlInAs, InGaSb, GaAsSb, and GaAsP. The group IV material may be Si or Ge. However, a group III-V material and a group IV material available in an integrated circuit semiconductor device according to embodiments of the present inventive concept are not necessarily limited to the above examples.

The group III-V material, and the group IV material, such as Ge, may be used as channel materials for manufacturing low-power and high-speed transistors. A high-performance complementary metal oxide semiconductor (CMOS) may be formed by using a semiconductor substrate including a group material having higher electron mobility than an Si substrate, such as GaAs, and a semiconductor substrate including a semiconductor material having higher hole mobility than an Si substrate, such as Ge In some embodiments, the substrate 10 may have a silicon on insulator (SOI) structure. In the present embodiment, the substrate 10 is described as using a silicon substrate for convenience of explanation.

A first well region 11a and a second well region 11b are formed in the substrate 10 to be spaced apart from each other (e.g., in the Y direction). The first well region 11a and the second well region 11b may be P-type well regions or N-type well regions. The P-type well regions are formed by implanting P-type impurities, e.g., boron, into the substrate 10. The N-type well regions are formed by implanting N-type impurities, e.g., arsenic or phosphorus, into the substrate 10.

A semiconductor stacking material layer STC is formed by alternately stacking sacrificial semiconductor layers 12 and semiconductor layers 14 for nanosheets on the substrate 10 (e.g., in the Z direction). The semiconductor stacking material layer STC includes a plurality of sacrificial semiconductor layers 12 and a plurality of semiconductor layers 14 for nanosheets. In an embodiment as shown in FIG. 5, four sacrificial semiconductor layers 12 and four semiconductor layers 14 for nanosheets are formed on the substrate 10. However, embodiments of the present inventive concept are not necessarily limited thereto.

The semiconductor stacking material layer STC is formed on the surface 10a of the substrate 10. The semiconductor stacking material layer STC may be formed on a first level SL1 of the substrate 10. The sacrificial semiconductor layers 12 and the semiconductor layers 14 for nanosheets constituting the semiconductor stacking material layer SIC may be formed by an epitaxial growth method. The sacrificial semiconductor layers 12 and the semiconductor layers 14 for nanosheets may include different semiconductor materials.

In some embodiments, the sacrificial semiconductor layers 12 may include SiGe, and the semiconductor layers 14 for nanosheets may include Si. However, embodiments of the present disclosure are not necessarily limited thereto. The sacrificial semiconductor layers 12 may include a material that is well etched with respect to the semiconductor layers 14 for nanosheets. In an embodiment, all of the sacrificial semiconductor layers 12 and the semiconductor layers 14 for nanosheets may be formed to have the same thickness. However, embodiments of the present inventive concept are not necessarily limited thereto.

First mask patterns 18 are formed on the semiconductor stacking material layer STC to be spaced apart from each other (e.g., in the Y direction). The first mask patterns 18 are formed above the first well region 11a and above the second well region lib. The first mask patterns 18 include hard mask patterns.

In an embodiment, the first mask patterns 18 may include silicon nitride, polysilicon, a spin-on hardmask (SOH) material, or a combination thereof. However, embodiments of the present inventive concept are not necessarily limited to the above examples. In an embodiment, the SOH material may include a hydrocarbon compound or a derivative thereof having a relatively high carbon content in a range of about 85 wt % to about 99 wt % on the basis of the total weight of the SOH material.

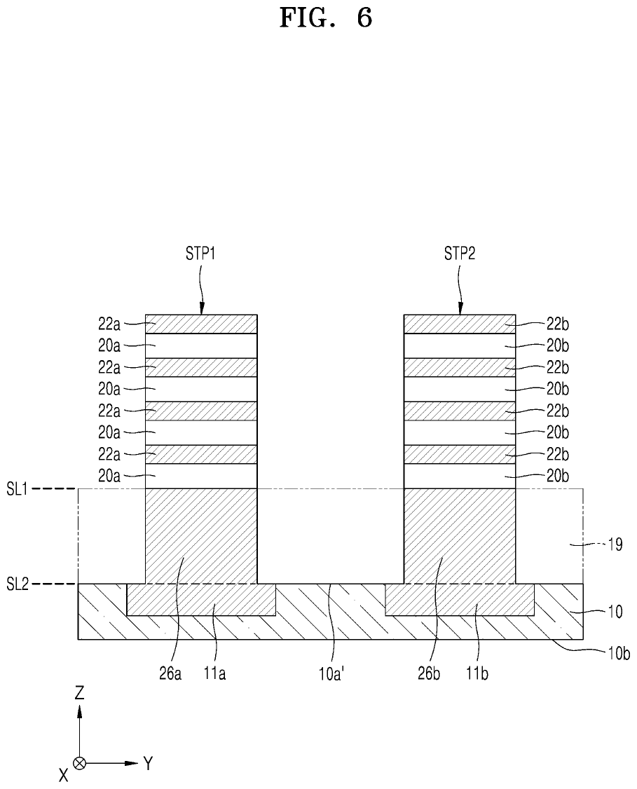

Referring to FIG. 6, a trench 19 is formed by etching a portion of the semiconductor stacking material layer STC and the substrate 10 by using the first mask patterns 18 of FIG. 5 as an etch mask. Accordingly, the substrate 10 has formed thereon active fins, such as first and second active fins 26a and 26b, defined by the trench 19, and semiconductor stacking patterns STP1 and STP2 spaced apart from each other on the first and second active fins 26a and 26b.

The first and second active fins 26a and 26b may be active regions of an integrated circuit semiconductor device. In an embodiment, the active fins may include a first active fin 26a and a second active fin 26b. However, embodiments of the present inventive concept are not necessarily limited thereto. The first active fin 26a may have the same body as the first well region 11a. The second active fin 26b may have the same body as the second well region lib.

The active fins, such as the first and second active fins 26a and 26b may be formed by etching a portion of the substrate 10. The first and second active fins 26a and 26b may be formed by etching the surface 10a of FIG. 5 of the substrate 10, such as from the first level SL1 to a second level SL2 of the substrate 10. After forming the active fins 26a and 26b, a surface 10a′ of the substrate 10 may be located at the second level SL2. Accordingly, the active fins 26a and 26b may protrude beyond the surface 10a1 of the substrate 10.

The semiconductor stacking patterns SIM and STP2 may include a first semiconductor stacking pattern STP1 and a second semiconductor stacking pattern STP2. The first semiconductor stacking pattern STP1 may include first semiconductor patterns 20a and first nanosheets 22a. The second semiconductor stacking pattern STP2 may include second semiconductor patterns 20b and second nanosheets 22b. The first mask patterns 18 of FIG. 5 are removed.

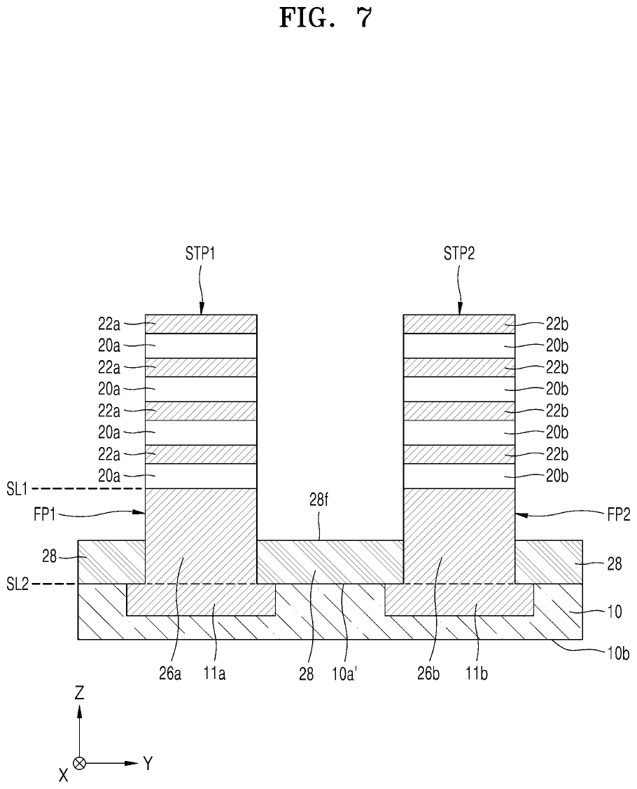

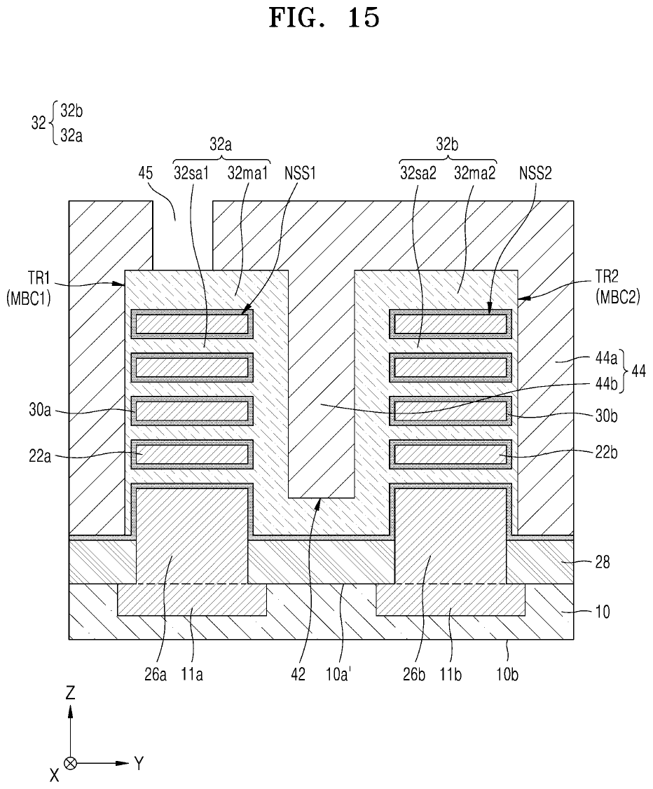

Referring to FIG. 7, an isolation layer 28 is formed within the trench 19 of FIG. 6. The isolation layer 28 may surround portions of lower portions of the active fins 26a and 26b. In some embodiments, the isolation layer 28 may be formed by filling an isolation material layer within the trench 19 of FIG. 16 and then recess etching the isolation material layer. In an embodiment, the recess etching may include a dry etching process, a wet etching process, or a combination of the dry etching process and the wet etching process.

In some embodiments, the isolation layer 28 may be formed from an oxide layer. In some embodiments, the isolation layer 28 may include an oxide layer formed by a deposition process or a coating process. In some embodiments, the isolation layer 28 may include an oxide layer formed by a flowable chemical vapor deposition (FCVD) process or a spin coating process.

For example, in an embodiment the isolation layer 28 may include fluoride silicate glass (FSG), undoped silicate glass (USG), born-phospho-silicate glass (BPSG), phospho-silicate glass (PSG), flowable oxide (FOX), plasma enhanced tetra-ethyl-ortho-silicate (PE-TEOS), or tonen silazene (TOSZ), but is not limited thereto.

When forming the isolation layer 28, the active fins 26a and 26b may protrude beyond a surface 28f of the isolation layer 28 by the recess etching of the isolation material layer. The first active fin 26a may include a first fin protrusion FP1 protruding from the surface 28f of the isolation layer 28. The second active fin 26b may include a second fin protrusion FP2 protruding from the surface 28f of the isolation layer 28.

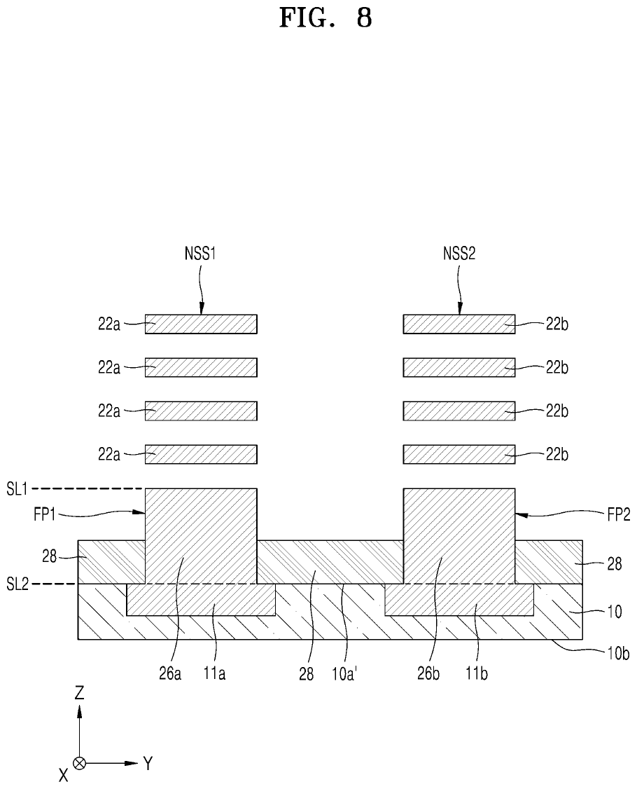

Referring to FIG. 8, nanosheet stacking structures, such as first and second nanosheet stacking structures NSS1 and NSS2, which are spaced apart from each other (e.g., in the Y direction), are formed by removing the first semiconductor patterns 20a constituting the first semiconductor stacking pattern STP1 of FIG. 7, and the second semiconductor patterns 20b constituting the second semiconductor stacking pattern STP2 of FIG. 7.

In an embodiment, the nanosheet stacking structures may include a first nanosheet stacking structure NSS1 and a second nanosheet stacking structure NSS2. However, embodiments of the present disclosure are not necessarily limited thereto. The first nanosheet stacking structure NSS1 may include a plurality of first nanosheets 22a formed above the first active fin 26a and spaced apart from each other (e.g., in the Z direction), The second nanosheet stacking structure NSS2 may include a plurality of second nanosheets 22b formed above the second active fin 26b and spaced apart from each other (e.g., in the Z direction).

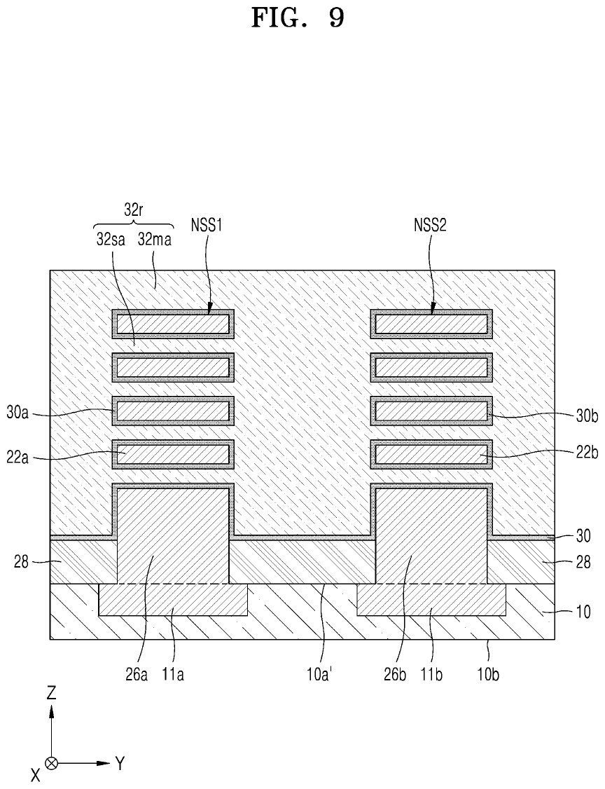

Referring to FIG. 9, first and second gate insulating layers 30a and 30b are formed to surround surfaces of the active fins, such as the first and second active fins 26a and 26b, and the first and second nanosheets 22a and 22b, In an embodiment, the gate insulating layers 30a and 30b may include a first gate insulating layer 30a and a second gate insulating layer 30b.

The first gate insulating layer 30a may be formed to surround the surface of the first active fin 26a, and the first nanosheets 22a. The second gate insulating layer 30b may be formed to surround the surface of the second active fin 26b, and the second nanosheets 22b.

The gate insulating layers 30a and 30b may include high dielectric layers. In an embodiment, the high dielectric layers may include a material having a higher dielectric constant than a silicon oxide layer. For example, the high dielectric layers may have a dielectric constant in a range of about 10 to about 25.

In an embodiment, the high dielectric layers may include a material selected from hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof. However, embodiments of the present inventive concept are not necessarily limited thereto and a material constituting the high dielectric layers may vary.

In an embodiment, the high dielectric layers may be formed by an atomic layer deposition (ALD), chemical vapor deposition (CVD), or physical vapor deposition (PVD) process. In an embodiment, the high dielectric layers may have a thickness in a range of about 10 Å to about 40 Å. However, embodiments of the present inventive concept are not necessarily limited thereto.

A gate electrode material layer 32r is formed on the gate insulating layers 30a and 30b, between the first nanosheets 22a, and between the second nanosheets 22b. The gate electrode material layer 32r is formed to be buried between the first nanosheets 22a and between the second nanosheets 22b. The gate electrode material layer 32r is formed to have a sufficient thickness to cover the first and second nanosheet stacking structures NSS1 and NSS2.

The gate electrode material layer 32r may include a sub gate electrode material layer 32sa formed between the first nanosheets 22a and between the second nanosheets 22b, and a main gate electrode material layer 32ma formed on the nanosheet stacking structures NSS1 and NSS2 and between the nanosheet stacking structures NSS1 and NSS2.

In some embodiments, the gate electrode material layer 32r may include a metal layer or a metal nitride layer. The gate electrode material layer 32r may include at least one selected from Ti, W, Al, Ru, Nb, Mo, Hf, Ni, Co, Pt, Yb, Tb, Dy, Er, Pd, TiN, TaN, and combinations thereof.

Referring to FIG. 10, a second mask layer 34 is formed on the gate electrode material layer 32r. The second mask layer 34 is formed to cover the first and second nanosheet stacking structures NSS1 and NSS2. The second mask layer 34 may be a mask layer for cutting the gate electrode material layer 32r.

The second mask layer 34 may include a hard mask layer. In an embodiment, the second mask layer 34 may include silicon nitride, polysilicon, a spin-on hardmask (SOH) material, or a combination thereof. However, embodiments of the present inventive concept are not necessarily limited thereto. In an embodiment, the SOH material may include a hydrocarbon compound or a derivative thereof having a relatively high carbon content in a range of about 85 wt % to about 99 wt % on the basis of the total weight of the SOH material.

A spare gate cutting region 36r and a gate electrode material pattern 32rp are formed by etching the gate electrode material layer 32r by using the second mask layer 34 as an etch mask. The spare gate cutting region 36r may be a hole region formed in the gate electrode material layer 32r of FIG. 9.

The spare gate cutting region 36r may be formed to be spaced apart from outer sidewalls of the first nanosheet stacking structure NSS1 and the second nanosheet stacking structure NSS2 (e.g., in the Y direction). In a third direction (a Z direction), an inner wall 36s1 of the spare gate cutting region 36r may be aligned with a sidewall 34s1 of the second mask layer 34.

The gate electrode material pattern 32rp may include a sub gate electrode material pattern 32sa′ formed between the first nanosheets 22a and between the second nanosheets 22b, and a main gate electrode material pattern 32ma′ formed on (e.g., directly above) the nanosheet stacking structures NSS1 and NSS2 and between the nanosheet stacking structures NSS1 and NSS2.

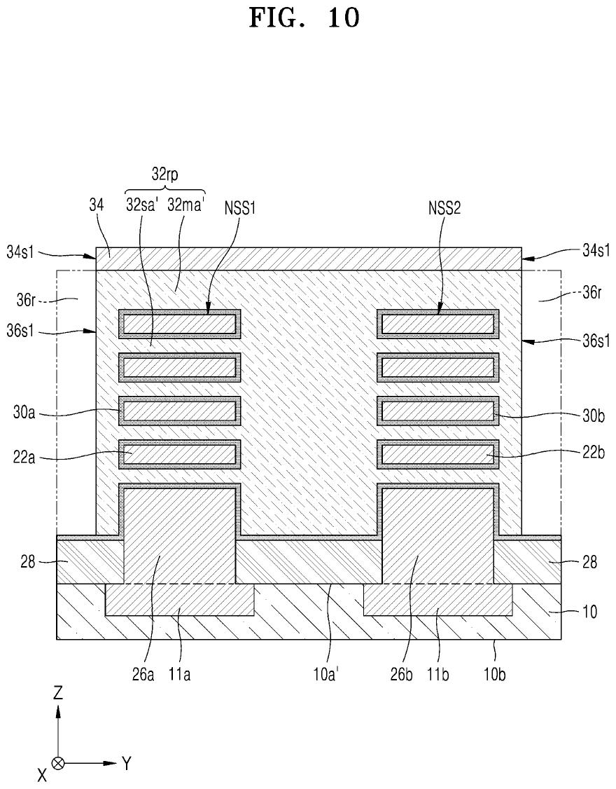

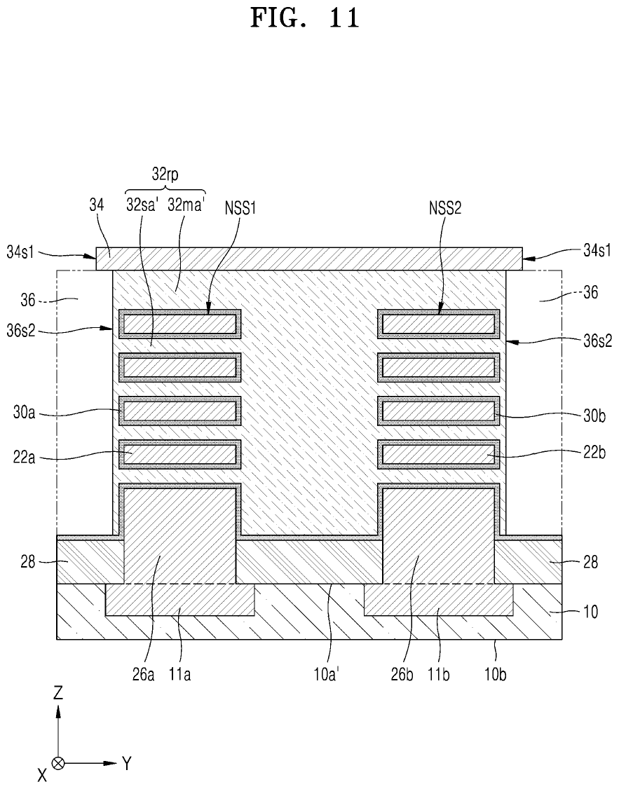

Referring to FIG. 11, a gate cutting region 36 is formed by further etching the gate electrode material pattern 32rp by using the second mask layer 34 as an etch mask. The gate electrode material pattern 32rp in contact with the spare gate cutting region 36r of FIG. 10 is further etched.

In the third direction (the Z direction), an inner wall 36s2 of the gate cutting region 36 is not aligned with the sidewall 34s1 of the second mask layer 34. In a second direction (a Y direction or -Y direction), the inner wall 36s2 of the gate cutting region 36 may be positioned inward from the sidewall 34s1 of the second mask layer 34.

Further etching of the gate electrode material pattern 32rp may reduce a width of the gate electrode material pattern 32rp formed on the outer sidewalls of the first nanosheet stacking structure NSS1 and the second nanosheet stacking structure NSS2. For example, due to further etching of the gate electrode material pattern 32rp, a width and height of sidewalls of gate electrodes may be determined via subsequent processes.

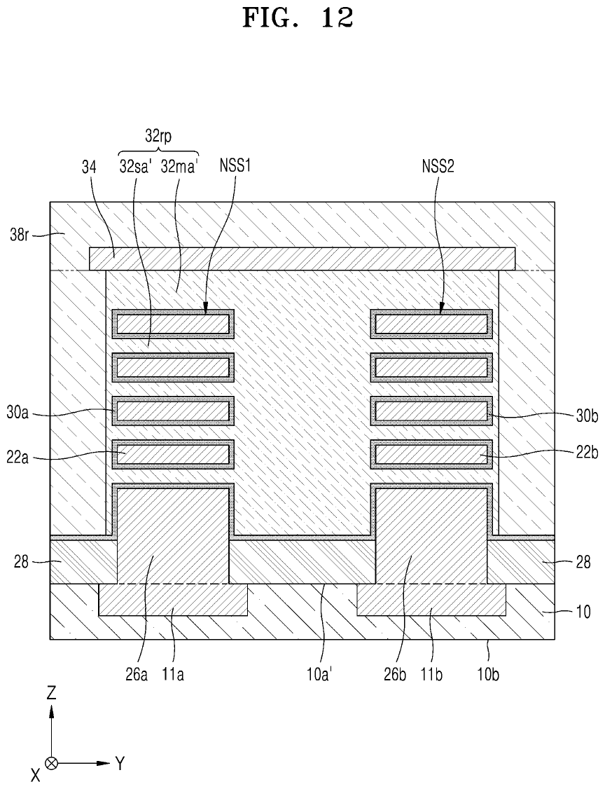

Referring to FIG. 12, a third mask layer 38r is formed to have a sufficient thickness to cover the second mask layer 34, the gate electrode material pattern 32rp, and the gate cutting region 36. The third mask layer 38r may be formed inside and on (e.g., directly above) the gate cutting region 36 of FIG. 11, and on the second mask layer 34. In an embodiment, the third mask layer 38r may be formed from a photoresist layer.

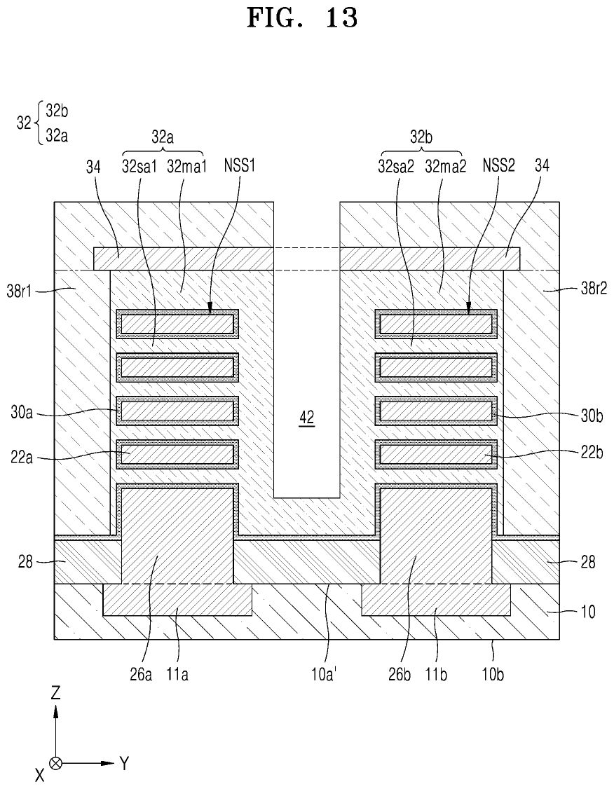

Referring to FIG. 13, the third mask layer 38r is patterned by a photolithography process to form third mask patterns 38r1 and 38r2 spaced apart from each other (e.g., in the Y direction). The third mask pattern 38r1 is formed on (e.g., formed directly thereon) the gate electrode material pattern 32rp of FIG. 12 to cover the first nanosheet stacking structure NSS1. The third mask pattern 38r2 is formed on (e.g., formed directly thereon) the gate electrode material pattern 32rp of FIG. 12 to cover the second nanosheet stacking structure NSS2.

A gate electrode 32 and a recess region 42 are formed by etching the second mask layer 34 and the gate electrode material pattern 32rp of FIG. 12 by using the third mask patterns 38r1 and 38r2 as an etch mask. The gate electrode 32 includes a first gate electrode 32a and a second gate electrode 32b.

The first gate electrode 32a may be formed on the first gate insulating layer 30a on the first nanosheet stacking structure NSS1. The first gate electrode 32a may include a first sub gate electrode 32sa1 formed between the first nanosheets 22a, and a first main gate electrode 32ma1 formed on top and sidewalls of the first nanosheets 22a.

The second gate electrode 32h may be formed on the second gate insulating layer 30b on the second nanosheet stacking structure NSS2. The second gate electrode 32b may include a second sub gate electrode 32sa2 formed between the second nanosheets 22b, and a second main gate electrode 32ma2 formed on top and sidewalls of the second nanosheets 22b.

The recess region 42 is formed between the first nanosheet stacking structure NSS1 and the second nanosheet stacking structure NSS2 (e.g, in the Y direction). The recess region 42 may be formed between the first gate electrode 32a and the second gate electrode 32b. A width and a height of sidewalk of the first gate electrode 32a and the second gate electrode 32b described above may be determined due to the formation of the recess region 42.

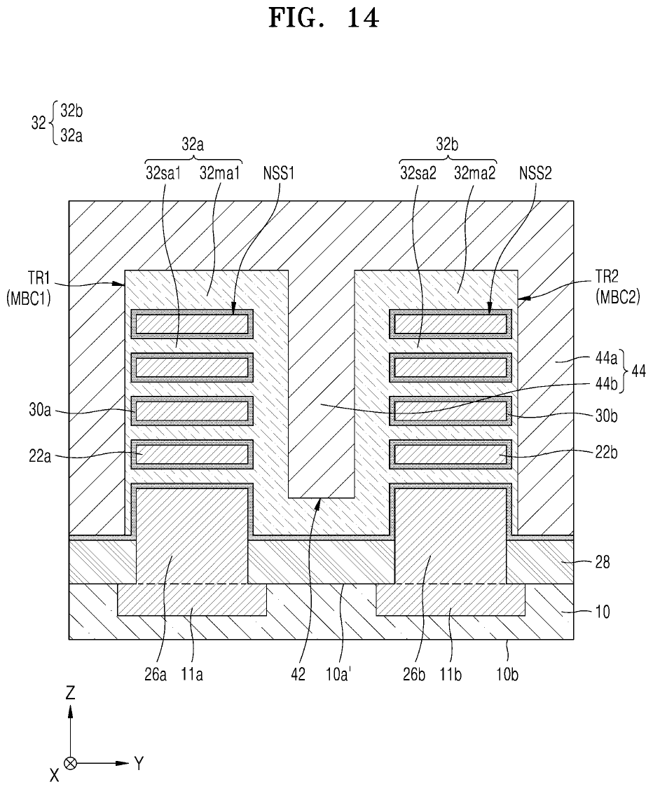

Referring to FIGS. 14 and 15, the third mask patterns 38r1 and 38r2 of FIG. 13 and the second mask layer 34 of FIG. 13 are removed. As shown in FIG. 14, an interlayer insulating layer 44 is formed on the gate electrode 32 in which the recess region 42 is formed. The interlayer insulating layer 44 may include a first portion 44a formed on top and a side-wall of the gate electrode 32, and a second portion 44b buried in the recess region 42.

As shown in FIG. 15, a contact hole 45 exposing the first gate electrode 32a (e.g., an upper surface of the first gate electrode 32a) is formed inside the interlayer insulating layer 44 on the first gate electrode 32a. As shown in FIG. 3, the contact hole 45 is filled to form a gate contact (46 of FIG. 3) connected to the first gate electrode 32a. An integrated circuit semiconductor device (100 of FIGS. 3 and 4) may be manufactured through manufacturing processes described above.

FIG. 16 is a block diagram illustrating a structure of a semiconductor chip including an integrated circuit semiconductor device, according to an embodiment.

In an embodiment, a semiconductor chip 200 may include a logic region 202, a static random access memory (SRAM) region 204, and an input/output region 206, The logic region 202 may include a logic cell region 203. The SRAM region 204 may include an SRAM cell region 205 and an SRAM peripheral circuit region 208. A first transistor 210 may be arranged in the logic cell region 203, and a second transistor 212 may be arranged in the SRAM cell region 205. A third transistor 214 may be formed in the SRAM peripheral circuit region 208, and a fourth transistor 216 may be arranged in the input/output region 206.

The semiconductor chip 200 may include an integrated circuit semiconductor device 100 of FIGS. 1 to 4 according to an embodiment. In some embodiments, the first transistor 210, the second transistor 212, the third transistor 214, and the fourth transistor 216 may include the first multi-bridge channel transistors MBC1 or the second multi-bridge channel transistors MBC2 described above.

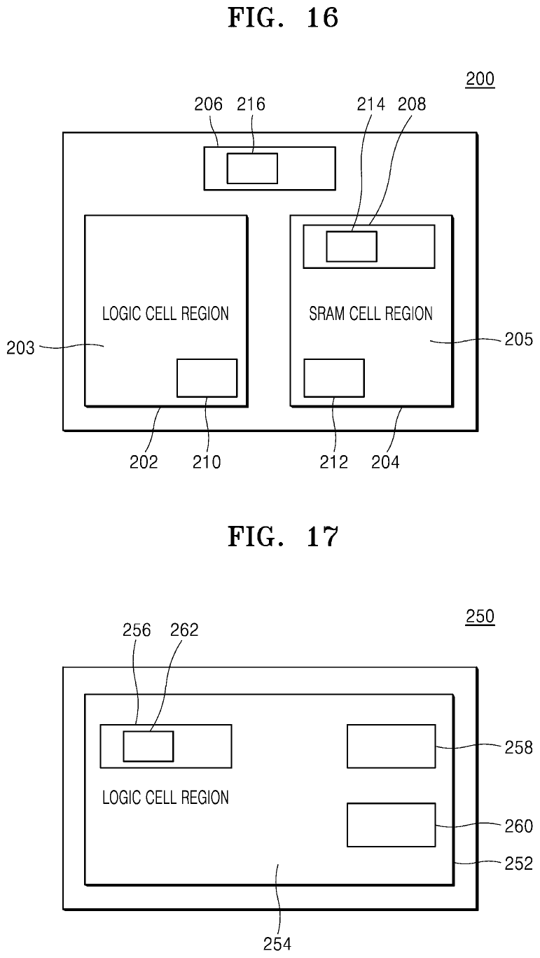

FIG. 17 is a block diagram illustrating a structure of a semiconductor chip including an integrated circuit semiconductor device, according to an embodiment.

In an embodiment, a semiconductor chip 250 may include a logic region 252. The logic region 252 may include a logic cell region 254 and an input/output region 256. A first transistor 258 and a second transistor 260 may be arranged in the logic cell region 254. The first transistor 258 and the second transistor 260 may be transistors having different conductive types. A third transistor 262 may be arranged in the input/output region 256.

The semiconductor chip 250 may include an integrated circuit semiconductor device 100 of FIGS. 1 to 4 according to an embodiment. In some embodiments, the first transistor 258, the second transistor 260, and the third transistor 262 may include the first multi-bridge channel transistors MBC1 or the second multi-bridge channel transistors MBC2 described above.

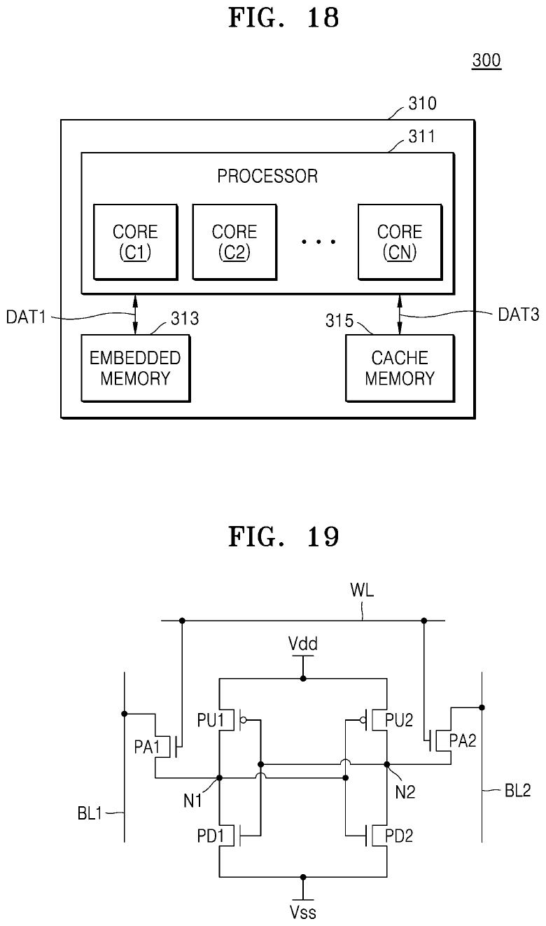

FIG. 18 is a block diagram illustrating a structure of an electronic device including an integrated circuit semiconductor device, according to an embodiment.

In an embodiment, an electronic device 300 may include a system on chip 310. The system on chip 310 may include a processor 311, an embedded memory 313, and a cache memory 315. The processor 311 may include one or more processor cores C1 to CN. The processor cores C1 to CN may process data and signals. The processor cores C1 to CN may include an integrated circuit semiconductor device 100 of FIGS. 1 to 4 according to embodiments.

The electronic device 300 may perform a unique function by using processed data and signals. For example, the processor 311 may be an application processor. The embedded memory 313 may exchange first data with the processor 311. The first data DAT1 is data that is processed or to be processed by the processor cores C1 to CN. The embedded memory 313 may manage the first data DAT1. For example, the embedded memory 313 may buffer the first data DAT1. The embedded memory 313 may operate as a buffer memory or a working memory of the processor 311.

The embedded memory 313 may be SRAM. The SRAM may operate at a higher speed than dynamic random access memory (DRAM). When the SRAM is embedded in the system on chip 310, the electronic device 300, which has a small size and operates at a high speed, may be implemented In addition, when the SRAM is embedded in the system on chip 310, consumption of active power of the electronic device 300 may be reduced.

For example, the SRAM may include the integrated circuit semiconductor device 100 of FIGS. 1 to 4 according to embodiments. The cache memory 315 may be mounted on the system on chip 310 together with the processor cores C1 to CN. The cache memory 315 may store cache data DATc. The cache data DATc may be data used by the processor cores C1 to CN. The cache memory 315 may have a smaller storage capacity, but may operate at an extremely high speed.

For example, the cache memory 315 may include SRAM including the integrated circuit semiconductor device 100 of FIGS. 1 to 4 according to embodiments. When the cache memory 315 is used, the number of times the processor 311 accesses the embedded memory 313 and a time at which the processor 311 accesses the embedded memory 313 may be reduced. Therefore, when the cache memory 315 is used, an operation speed of the electronic device 300 may increase. For better understanding, FIG. 18 illustrates that the cache memory 315 is a separate element from the processor 311. However, in some embodiments the cache memory 315 may be included in the processor 311.

FIG. 19 is an equivalent circuit diagram of an SRAM cell, according to an embodiment.

In an embodiment, the SRAM cell may be implemented via an integrated circuit semiconductor device 100 of FIGS. 1 to 4 according to an embodiment. For example, the SRAM cell may be applied to the embedded memory 313 and/or the cache memory 315 described with reference to FIG. 18.

The SRAM cell may include a first pull-up transistor PU1, a first pull-down transistor PD1, a second pull-up transistor PU2, a second pull-down transistor PD2, a first access transistor PA1, and a second access transistor PA2.

In an embodiment, the first and second pull-up transistors PU1 and PU2 may be P-type metal oxide semiconductor (MOS) transistors and the first and second pull-down transistors PD1 and PD2, and the first and second access transistors PA1 and PA2 may be N-type MOS transistors.

The first pull-up transistor PU1 and the first pull-down transistor PD1 may constitute a first inverter. Gate electrodes (e.g., gates) of the first pull-up transistor PU1 and the first pull-down transistor and PD1, which are connected to each other, may correspond to an input terminal of the first inverter, and a first node N1 may correspond to an output terminal of the first inverter.

The second pull-up transistor PU2 and the second pull-down transistor PD2 may constitute a second inverter. Gate electrodes (e.g., gates) of the second pull-up transistor PU2 and the second pull-down transistor PD2, which are connected to each other, may correspond to an input terminal of the second inverter, and a second node N2 may correspond to an output terminal of the second inverter.

The first inverter may be combined with the second inverter to constitute a latch structure. The gate electrodes of the first pull-up transistor PU1 and the first pull-down transistor PD1 may be electrically connected to the second node N2, and the gates of the second pull-up transistor PU2 and the second pull-down transistor PU2 may be electrically connected to the first node N1.

A first source/drain of the first access transistor PA1 may be connected to the first node N1, and a second source/drain of the first access transistor PA1 may be connected to a first bitline BL1. A first source/drain of the second access transistor PA2 may be connected to the second node N2, and a second source/drain of the second access transistor PA2 may be connected to a second bitline BL2.

Gate electrodes of the first and second access transistors PA1 and PA2 may be electrically connected to a wordline WL. Accordingly, the SRAM cell may be implemented by using an integrated circuit semiconductor device 100 of FIGS. 1 to 4 according to embodiments.

While the present inventive concept has been particularly shown and described with reference to non-limiting embodiments thereof, it will be understood that various changes in form and details may be made therein without departing from the spirit and scope of the following claims.

What is claimed is:

1. An integrated circuit semiconductor device comprising:
a first transistor on a substrate, the first transistor includes a first gate electrode; and
a second transistor on the substrate and spaced apart from the first transistor, the second transistor includes a second gate electrode that is directly connected to the first gate electrode, a recess region that is recessed in surfaces of the first gate electrode and the second gate electrode and is arranged between the first gate electrode and the second gate electrode,
wherein a first width of a first sidewall of the first gate electrode is less than a second width of a second sidewall of the first gate electrode adjacent to the recess region and opposite the first sidewall, and
wherein a third width of a third sidewall of the second gate electrode is less than a fourth width of a fourth sidewall of the second gate electrode adjacent to the recess region and opposite the third sidewall.

2. The integrated circuit semiconductor device of claim 1, wherein the first transistor and the second transistor include multi-bridge channel transistors.

3. The integrated circuit semiconductor device of claim 2, wherein:
the first transistor includes a first nanosheet stacking structure including a plurality of first nanosheets spaced apart from each other in a direction perpendicular to an upper surface of the substrate, and a first gate insulating layer surrounding the plurality of first nanosheets; and
the second transistor includes a second nanosheet stacking structure including a plurality of second nanosheets spaced apart from each other in the direction perpendicular to the upper surface of the substrate, and a second gate insulating layer surrounding the plurality of second nanosheets.

4. The integrated circuit semiconductor device of claim 1, wherein:
the first transistor is disposed on a first active fin extending in a first direction on the substrate and,
the second transistor is disposed on a second active fin that is spaced apart from the first active fin in a second direction perpendicular to the first direction on the substrate, the second active fin extending in the first direction.

5. The integrated circuit semiconductor device of claim 4, wherein the first width, the second width, the third width, and the fourth width extend in the second direction.

6. The integrated circuit semiconductor device of claim 1, wherein the first gate electrode and the second gate electrode have a same body as each other.

7. The integrated circuit semiconductor device of claim 1, wherein the first width is equal to the third width, and the second width is equal to the fourth width.

8. An integrated circuit semiconductor device comprising:
a first active fin on a substrate;
a first multi-bridge channel transistor on the first active fin, the first multi-bridge channel transistor includes a first gate electrode;
a second active fin on the substrate and spaced apart from the first active fin; and
a second multi-bridge channel transistor on the second active fin, the second multi-bridge channel transistor includes a second gate electrode that is directly connected to the first gate electrode, a recess region that is recessed in surfaces of the first gate electrode and the second gate electrode and is arranged between the first gate electrode and the second gate electrode,
wherein a first height of a first sidewall of the first gate electrode is greater than a second height of a second sidewall of the first gate electrode adjacent to the recess region and opposite the first sidewall, and
wherein a third height of a third sidewall of the second gate electrode is greater than a fourth height of a fourth sidewall of the second gate electrode adjacent to the recess region and opposite the third sidewall.

9. The integrated circuit semiconductor device of claim 8, wherein:
an isolation layer is disposed on the substrate, the isolation layer electrically isolating the first active fin and the second active fin from each other;
the first active fin includes a first fin protrusion protruding from a surface of the isolation layer; and
the second active fin includes a second fin protrusion protruding from the surface of the solation layer.

10. The integrated circuit semiconductor device of claim 9, wherein a bottom portion of the recess region is positioned at a lower level than upper surfaces of the first fin protrusion and the second fin protrusion.

11. The integrated circuit semiconductor device of claim 9, wherein:
the first multi-bridge channel transistor includes a first nanosheet stacking structure including a plurality of first nanosheets spaced apart from each other in a direction perpendicular to an upper surface of the substrate, and a first gate insulating layer surrounding the plurality of first nanosheets; and
the second multi-bridge channel transistor includes a second nanosheet stacking structure including a plurality of second nanosheets spaced apart from each other in the direction perpendicular to the surface of the substrate, and a second gate insulating layer surrounding the plurality of second nanosheets.

12. The integrated circuit semiconductor device of claim 9, wherein the first active fin is disposed on the substrate to extend in a first direction, and the second active fin is disposed on the substrate and is spaced apart from the first active fin in a second direction perpendicular to the first direction, the second active fin extending in the first direction.

13. The integrated circuit semiconductor device of claim 12, wherein the first direction is a channel length direction of the first multi-bridge channel transistor and the second multi-bridge channel transistor, and the second direction is a channel width direction of the first multi-bridge channel transistor and the second multi-bridge channel transistor.

14. The integrated circuit semiconductor device of claim 9, wherein the first gate electrode and the second gate electrode have a same body as each other.

15. The integrated circuit semiconductor device of claim 9, wherein the first height is equal to the third height, and the second height is equal to the fourth height.

16. An integrated circuit semiconductor device comprising:
a first active fin on a substrate;
a first multi-bridge channel transistor on the first active fin, the first multi-bridge channel transistor includes a first gate electrode;
a second active fin on the substrate and spaced apart from the first active fin; and
a second multi-bridge channel transistor on the second active fin, the second multi-bridge channel transistor includes a second gate electrode that is directly connected to the first gate electrode, a recess region that is recessed in surfaces of the first gate electrode and the second gate electrode and is arranged between the first gate electrode and the second gate electrode,
wherein a first width of a first sidewall of the first gate electrode is less than a second width of a second sidewall of the first gate electrode adjacent to the recess region and opposite the first sidewall, a third width of a third sidewall of the second gate electrode is less than a fourth width of a fourth sidewall of the second gate electrode adjacent to the recess region and opposite the third sidewall,
wherein a first height of the first sidewall of the first gate electrode is greater than a second height of the second sidewall of the first gate electrode adjacent to the recess region and opposite the first sidewall, and a third height of the third sidewall of the second gate electrode is greater than a fourth height of the fourth sidewall of the second gate electrode adjacent to the recess region and opposite the third sidewall.

17. The integrated circuit semiconductor device of claim 16, wherein:
the first active fin is disposed on the substrate to extend in a first direction and the second active fin is disposed on the substrate and is spaced apart from the first active fin in a second direction perpendicular to the first direction, the second active fin extending in the first direction; and
the first multi-bridge channel transistor includes a first nanosheet stacking structure including a plurality of first nanosheets spaced apart from each other in a direction perpendicular to an upper surface of the substrate on the first active fin, and a first gate insulating layer surrounding the plurality of first nanosheets, and the second multi-bridge channel transistor includes a second nanosheet stacking structure including a plurality of second nanosheets spaced apart from each other in the direction perpendicular to the upper surface of the substrate on the second active fin, and a second gate insulating layer surrounding the second nanosheets.

18. The integrated circuit semiconductor device of claim 17, wherein:
the first width, the second width, the third width, and the fourth width extend in the second direction; and
the first width is equal to the third width; and
the second width is equal to the fourth width.

19. The integrated circuit semiconductor device of claim 16, wherein the first gate electrode and the second gate electrode have a same body as each other.

20. The integrated circuit semiconductor device of claim 16, wherein:
an isolation layer is disposed on the substrate, the isolation layer electrically isolating the first active fin and the second active fin from each other;
the first active fin includes a first fin protrusion protruding from a surface of the isolation layer; and
the second active fin includes a second fin protrusion protruding from the surface of the isolation layer,
wherein a bottom portion of the recess region is positioned at a lower level than upper surfaces of the first fin protrusion and the second fin protrusion.
